(19) United States
(12) Patent Application Publication
(10) Pub. No.: US 2015/0170890 A1
(43) Pub. Date: Jun. 18, 2015

(54) Sputtering Target

(71) Applicant: JX Nippon Mining & Metals Corporation, Tokyo (JP)

(72) Inventor: Yuki Ikeda, Ibaraki (JP)

(21) Appl. No.: 14/402,024

(22) PCT Filed: Sep. 13, 2013
(86) PCT No.: PCT/JP2013/074840

§ 371 Date: Nov. 18, 2014

(30) Foreign Application Priority Data
Sep. 18, 2012 (JP) 2012-204332

(51) Int. Cl. H01J 37/34; G11B 5/851; G11B 5/65; C23C 14/08

(52) U.S. Cl. CPC H01J 37/3429; C23C 14/08; G11B 5/851; G11B 5/656; H01J 2237/332

(57) ABSTRACT

Provided is a sputtering target composed of a metal matrix phase containing Co and a phase containing 6 to 25 mol % of an oxide that is dispersed in the form of grains (hereinafter, referred to as “oxide phase”); and the sputtering target is characterized in that the integral width of the highest peak among single peaks of XRD is 0.7 or less. A non-magnetic material grain-dispersed sputtering target is provided, which does not undergo the formation of initial particles during sputtering to thereby shorten a burn-in time and which enables the generation of steady discharge during sputtering.

### TECHNICAL FIELD

The present invention relates to a sputtering target that is used for forming a magnetic material thin film for a magnetic recording medium, in particular, a film for the magnetic recording layer of a hard disk employing a vertical magnetic recording system, and relates to a non-magnetic material grain-dispersed sputtering target that is low in the formation of initial particles and provides stable electric discharge during sputtering.

### BACKGROUND

In the field of magnetic recording represented by hard disk drives, ferromagnetic metals, such as Co, Fe, or Ni-based materials, are used as materials for magnetic thin films that carry out recording. For example, in recording layers of hard disks employing a longitudinal magnetic recording system, Co—Cr based or Co—Cr—Pt based ferromagnetic alloys mainly containing Co have been used.

In addition, in recording layers of hard disks employing a vertical magnetic recording system, which recently has been applied to practical use, composite materials composed of Co—Cr based or Co—Cr—Pt based ferromagnetic alloys mainly containing Co and nonmagnetic inorganic materials are widely used.

In many cases, magnetic thin films of magnetic recording media such as hard disks are produced by sputtering a ferromagnetic material sputtering target composed of the above-mentioned materials because of its high productivity.

As methods of producing these ferromagnetic material sputtering targets, a melting method and a powder metallurgy method are proposed. Though which method is used for producing a target is determined depending on the characteristic requirements, sputtering targets composed of ferromagnetic alloys and nonmagnetic inorganic grains, which are used in recording layers of hard disks using a vertical magnetic recording system, are usually produced by the powder metallurgy method. This is because the inorganic material grains are required to be uniformly dispersed in the alloy base material, but it is difficult to produce the target by the melting method.

For example, a method of preparing a sputtering target for a magnetic recording medium by mixing a powder mixture prepared by mixing a Co powder, a Cr powder, a TiO₂ powder, and a SiO₂ powder with a Co spherical powder using a planetary motion mixer and molding the resulting powder mixture by hot pressing has been proposed (Patent Literature 1).

The target structure in this case appears such that a metal base phase (A) containing inorganic grains dispersed therein surrounds spherical metal phases (B) having a magnetic permeability higher than that of metal base phase (A) (FIG. 1 of Patent Literature 1). Such a structure is advantageous for improving the leakage magnetic flux, but is rather problematic from the viewpoint of inhibiting generation of particles during sputtering.

In general, a magnetic material target containing a metal such as Co, Cr, or Pt, and an oxide such as SiO₂, has a problem in that the generation of particles will increase during sputtering when the oxide phase exposing to the target surface has defects such as cracking or chippings due to machining. In order to solve this problem, conventionally, a machining method for reducing the surface roughness has been performed in many cases.

In a sputtering target composed of a single element not containing any oxide, a method of removing the processing strain for reducing initial particles by performing a non-machining process such as etching is known. However, in a magnetic material target composed of an alloy of, for example, Co, Cr, or Pt and further containing an oxide such as SiO₂, etching is not successfully performed, and therefore the surface roughness cannot be improved as in the production of a target of a single element.

As conventional technologies, Patent Literature 2 describes a technology for producing a sputtering target having a surface roughness Ra of 1.0 μm or less, a total amount of contaminant metal elements having high melting points, other than the main and alloy components, and Si, Al, Co, Ni, and B of 500 ppm or less, a hydrogen content of the surface of 50 ppm or less, and a work-affected layer having a thickness of 50 μm or less. The technology optionally performs a precision cutting process with, particularly, a diamond byte. Consequently, Patent Literature 2 describes a technology of forming a film having a uniform thickness on a substrate by sputtering the resulting target and preventing the generation of nodules during sputtering to inhibit the generation of particles. In this case, since non-magnetic grains composed of an oxide are not contained, the surface can be easily machined, and the generation of particles can be relatively easily prevented. However, unfortunately, this technology cannot be applied to an invention that the present invention tries to provide.

Patent Literature 3 describes a sputtering target for a magnetic recording film, composed of a matrix phase containing Co and Pt and a metal oxide phase and having a magnetic permeability of 6 to 15 and a relative density of 90% or more.

In the sputtering target for a magnetic recording film, the grains formed by the matrix phase and the grains formed by the metal oxide phase on the surface of the sputtering target both have an average grain size of 0.05 μm or more and less than 7.0 μm observed with an analytical scanning electron microscope, and the average grain size of the grains formed by the matrix phase is larger than that of the grains formed by the metal oxide phase.

In the sputtering target for a magnetic recording film, the X-ray diffraction peak intensity ratio represented by Expression (I) is 0.7 to 1.0 in X-ray diffraction analysis.

The X-ray diffraction peak intensity ratio represented by Expression (I) in this case refers to the ratio calculated by dividing the X-ray diffraction peak intensity of the [002] plane of Co by [(the X-ray diffraction peak intensity of the plane)+(the X-ray diffraction peak intensity of the [002] plane)], and it cannot be applied to an invention that the present invention tries to provide.

Patent Literature 4 describes a method of treating the surface of a sputtering target for shortening the burn-in time for sputtering by removing the surface deformation layer, wherein the target surface is subjected to extrusion hone polishing by bringing the target surface into a contact with a viscoelastic abrasive medium (VEAM) and relatively moving between the target surface and the medium. This is intended to remove the surface deformation layer, and since the target material in this case is metallic materials and does not contain non-magnetic grains of an oxide, the surface can be easily machined, and the generation of particles can be relatively easily prevented. However, unfortunately, this technology cannot be applied to the invention using non-magnetic grains of an oxide.

### CITATION LIST

### Patent Literature

Patent Literature 1: Japanese Patent No. 4673453
Patent Literature 2: Japanese Patent Laid-Open No. H11-1766
Patent Literature 3: Japanese Patent Laid-Open No. 2009-102707
Patent Literature 4: Published Patent Application, Japanese Translation of International Patent Application No. 2010-516900

### SUMMARY OF INVENTION

### Technical Problem

As described above, a magnetic material target containing a metal such as Co, Cr, or Pt, and an oxide such as SiO₂, has problems in that the generation of particles will increase during sputtering when the oxide phase exposing to the target surface has defects of cracking or chippings or the like due to machining. Even if the problem of cracking or chippings of the oxide phase due to machining is solved, the residual strain associated with surface processing will cause generation of particles. However, since the residual processing strain is not sufficiently grasped, a fundamental solution against the generation of particles, without influencing the method of processing the surface and the precision of the processing, has not been achieved yet.

### Solution to Problem

In order to solve the above-described problems, the present inventors have diligently studied and, as a result, have found that the formation of initial particles during sputtering can be inhibited, the burn-in time can be considerably shortened, and a non-magnetic material grain-dispersed sputtering target performing stable electric discharge during sputtering can be provided, by reducing the residual processing strain of a sputtering target and controlling the integral width of the highest peak among single peaks of XRD to a certain level or less by investigating the residual processing strain of the target by the XRD.

The present invention, based on these findings, provides:

1) A sputtering target comprising a metal matrix phase containing Co and a phase of dispersed oxide grains (hereinafter, referred to as “oxide phase”) in an amount of 6 to 25 mol %, wherein the integral width of the highest peak among single peaks of XRD is 0.7 or less.

The present invention also provides:

2) The sputtering target according to 1) above, wherein the metal matrix phase is composed of 5 mol % or more and 40 mol % or less of Cr and the remainder being Co and inevitable impurities.

The present invention also provides:

3) The sputtering target according to 1) above, wherein the metal matrix phase is composed of 5 mol % or more and 40 mol % or less of Cr, 5 mol % or more and 30 mol % or less of Pt, and the remainder being Co and inevitable impurities.

The present invention further provides:

4) The sputtering target according to any one of 1) to 3) above, wherein the oxide phase is composed of at least one oxide selected from SiO₂, TiO₂, Ti₂O₃, Cr₂O₃, Ta₂O₅, Ti₅O₉, B₂O₃, CoO, and Co₃O₄; and the amount of the oxide phase is 5 to 25 mol %.

The present invention further provides:

5) The sputtering target according to any one of 1) to 4) above, wherein the metal matrix phase contains at least one element selected from B, Ti, V, Mn, Zr, Nb, Ru, Mo, Ta, and W in an amount of 0.5 to 10 mol %.

### Effects of Invention

As described above, the present invention can inhibit the generation of initial particles during sputtering and can considerably shorten the burn-in time and thereby can provide a non-magnetic material grain-dispersed sputtering target performing stable electric discharge during sputtering. Consequently, the target lifetime is elongated to allow production of a magnetic material thin film at a low cost. Furthermore, the present invention has an advantageous effect of significantly improving the quality of the film formed by sputtering.

### DETAILED DESCRIPTION OF INVENTION

The sputtering target of the present invention is composed of a metal matrix phase containing Co and a phase of dispersed oxide grains (hereinafter, referred to as “oxide phase”) in an amount of 6 to 25 mol %. The sputtering target is characterized in that integral width of the highest peak among single peaks of XRD is 0.7 or less. This is an index of a reduction in residual processing strain. Thus, the residual processing strain can be reduced, the generation of initial particles caused by residual processing strain is reduced, and the burn-in time can be significantly shortened.

The typical composition of the metal matrix phase of the sputtering target of the present invention is composed of 5 mol % or more and 40 mol % or less of Cr and the remainder being Co and inevitable impurities or is composed of 5 mol % or more and 40 mol % or less of Cr, 5 mol % or more and 30 mol % or less of Pt, and the remainder being Co and inevitable impurities, and these sputtering targets are encompassed in the present invention.

These sputtering targets are ferromagnetic material sputtering targets that are used for forming magnetic material thin films of magnetic recording media, in particular, films for the magnetic recording layers of hard disks employing a vertical magnetic recording system.

The oxide phase is composed of at least one oxide selected from SiO₂, TiO₂, Ti₂O₃, Cr₂O₃, Ta₂O₅, Ti₅O₉, B₂O₃, CoO, and Co₃O₄. The target of the present invention contains 5 to 25 mol % of these oxides. Although examples described below show a part of these oxides, other oxides also have approximately the same functions.

Furthermore, the metal matrix phase of the sputtering target of the present invention can contain at least one element selected from B, Ti, V, Mn, Zr, Nb, Ru, Mo, Ta, and W in an amount of 0.5 to 10 mol %. These elements are optional elements as needed for improving the characteristics as magnetic recording media. Any content within the range mentioned above can maintain the characteristics as effective magnetic recording media.

The ferromagnetic material sputtering target of the present invention may be manufactured by the powder metallurgy method. Powders of respective metal element and optional powders of additional metal elements are prepared as needed. Preferably, a maximum grain size of these metal powders is 20 μm or less. Respective powder of the metal elements may be a powder of an alloy of the metal, in such cases also, preferably, the maximum grain size is 20 μm or less.

More preferably, the grain size is 0.1 μm or more since too small a grain size accelerates oxidation to cause problems such that the component composition is outside the intended range. Subsequently, these metal powders are weighed to obtain an intended composition, mixed and pulverized with well-known methods by using a ball mill and the like. When an inorganic material powder is also added, the powder may be mixed with the metal powders at this stage.

An oxide powder is prepared as the inorganic material powder; and preferably, the oxide powder has a maximum grain size of 5 μm or less. More preferably, the grain size is 0.1 μm or more since too small a grain size tend to aggregate.

As a part of the Co raw material, a Co coarse powder or a Co atomized powder is used. Here, the mixing ratio of the Co coarse powder or the Co atomized powder is adjusted such that the ratio of an oxide does not exceed 25 mol %. A Co atomized powder having a diameter in a range of 50 to 150 μm is prepared, and the Co atomized powder and the powder mixture described above are pulverized and mixed with an attritor. Here, as the mixer, for example, a ball mill or a mortar can be used, but it is preferable to use a strong mixing method such as a ball mill.

Alternatively, the prepared Co atomized powder may be separately pulverized into a Co coarse powder having a diameter in a range of 50 to 300 μm, and the coarse powder may be mixed with the powder mixture described above. The mixer is preferably, for example, a ball mill, a Pneugra-machine (agitator), a mixer, or a mortar. In light of the problem of oxidation during mixing, preferably, the mixing is performed in an inert gas atmosphere or in vacuum.

The ferromagnetic material sputtering target of the present invention is prepared by molding and sintering the obtained powder using a vacuum hot pressing device, and cutting the resulting product into an intended shape.

Note that the molding and sintering process is not limited to hot pressing, but may be performed by plasma discharge sintering or hot isostatic pressure sintering. The retention temperature for the sintering is preferably set to the lowest temperature in the temperature range in which the target is sufficiently densified. Though it varies depending on the composition of a target, in many cases, the temperature is in a range of 800° C. to 1200° C. Crystal growth of the sintered compact can be suppressed by performing the sintering at a lower temperature. The pressure during the sintering is preferably 300 to 500 kg/cm².

It is important to remove the residual processing strain, and thus rotary surface grinding and polishing with abrasive grains as finishing are performed after lathing. The evaluation of these processes is performed by observing the peaks of the XRD, and the integral width of the highest peak among single peaks of XRD is controlled to 0.7 or less.

The integral width of a crystal plane of the target measured by X-ray diffraction reflects the internal strain contained in the crystal plane that is the processing strain caused by plastic working during the production of the target or by machining such as cutting of the target. A larger integral width means a larger residual strain.

Since the final evaluation results vary depending on the type of the raw material and the surface processing, a certain degree of the process of trial and error is necessary for achieving the purpose. If a surface processing process is fixed once, the conditions for controlling the integral width of the highest peak among single peaks of XRD to 0.7 or less can be constantly achieved. These can be readily obtained by a person skilled in the art when the person clearly understands the present invention.

### EXAMPLES

The present invention will now be described by examples and comparative examples. The examples are merely exemplary and are not intended to limit the scope of the present invention. That is, the present invention is defined by the following claims only and encompasses various modifications in addition to the examples contained in the present invention.

### Example 1

A Co powder having an average grain size of 3 μm, a Cr powder having an average grain size of 5 μm, a Pt powder having an average grain size of 1 μm, a SiO₂ powder having an average grain size of 1 μm, and a Co coarse powder having a diameter in a range of 50 to 300 μm were prepared as raw material powders. The Co powder, the Cr powder, the Pt powder, the SiO₂ powder, and the Co coarse powder, were weighed to obtain a target composition 62Co-15Cr-15Pt-8SiO₂ (mol %).

Subsequently, the Co powder, the Cr powder, the Pt powder, and the SiO₂ powder were charged into a 10-liter ball mill pot together with zirconia balls as the pulverizing medium, and the ball mill pot was sealed and rotated for 20 hours for mixing. The resulting powder mixture and the Co coarse powder were charged into an attritor and were pulverized and mixed.

The resulting powder mixture was loaded in a carbon mold and was hot-pressed in a vacuum atmosphere under conditions of a temperature of 1100° C., a retention time of 2 hours, and a pressure of 30 MPa to obtain a sintered compact. The sintered compact was cut with a lathe and was then subjected to rotary surface grinding to obtain a disk-shaped target having a diameter of 180 mm and a thickness of 5 mm. The finishing quantity was 50 μm. These processes, finishing, and finishing quantity are shown in Table 1.

In order to estimate the residual strain remaining on the target surface, XRD was measured. The integral width of the peak at 50°, the highest of single peaks, was 0.6. Subsequently, sputtering was performed using the target. The number of particles was decreased to a background level (five particles) or less at the time of 0.4 kWh sputtering (burn-in) to obtain satisfactory results. The results are also shown in Table 1.

Since the production cannot be started during the burn-in (time), a shorter burn-in time is better. Generally, the burn-in time is preferably 1.0 kWh or less. The same is applied to the following examples and comparative examples.

TABLE 1

| | | | Finising quantity | Integral width | |
|---|---|---|---|---|---|
| | | Finishing | (μm) | of main peak | Burn-in |
| Example 1 | 62Co—15Cr—15Pt—8SiO₂ | rotary surface | 50 | 0.6 | 0.4 kWh |
| | | grinding | | | |
| Comparative | 62Co—15Cr—15Pt—8SiO₂ | surface grinding | 25 | 1.2 | not finished |
| Example 1 | | | | | even at 2.5 kWh |
| Comparative | 62Co—15Cr—15Pt—8SiO₂ | polishing | 1 | 0.8 | 1.4 kWh |
| Example 2 | | | | | |
| Comparative | 62Co—15Cr—15Pt—8SiO₂ | surface grinding | 25 + 1 | 0.8 | 1.3 kWh |
| Example 3 | | and polishing | | | |
| Example 2 | 54Co—20Cr—15Pt—5TiO₂—6CoO | surface grinding | 50 | 0.7 | 0.8 kWh |
| Comparative | 54Co—20Cr—15Pt—5TiO₂—6CoO | surface grinding | 25 | 1.1 | 2.3 kWh |
| Example 4 | | | | | |
| Example 3 | 61Co—15Cr—15Pt—3TiO₂—3SiO₂—3Cr₂O₃ | surface grinding | 25 + 1 | 0.7 | 0.9 kWh |
| | | and polishing | | | |
| Comparative | 61Co—15Cr—15Pt—3TiO₂—3SiO₂—3Cr₂O₃ | polishing | 1 | 1.3 | 2.8 kWh |
| Example 5 | | | | | |
| Example 4 | 60Co—30Cr—10TiO₂ | polishing | 1 | 0.6 | 0.7 kWh |
| Comparative | 60Co—30Cr—10TiO₂ | surface grinding | 25 | 1.2 | 1.3 kWh |
| Example 6 | | | | | |

### Comparative Example 1

Target materials having a composition 62Co-15Cr-15Pt-8SiO₂ (mol %) were prepared as in Example 1, and a target was produced as in Example 1 except that the machining after cutting with a lathe was performed by surface grinding finishing. The finishing quantity was 25 μm. In order to estimate the residual strain remaining on the target surface, XRD was measured. The integral width of the peak at 50°, the highest of single peaks, was 1.2, which exceeded the range of the present invention. The results of sputtering of the target are shown in Table 1. The number of particles was not decreased to a background level (five particles) or less even at 2.5 kWh sputtering.

### Comparative Example 2

Target materials having the same composition as that in Example 1 were produced into a target by performing machining after cutting with a lathe by polishing finishing. The finishing quantity was 1 μm. In order to estimate the residual strain remaining on the target surface, XRD was measured. The integral width of the peak at 50°, the highest of single peaks, was 0.8, which exceeded the range of the present invention. The results of sputtering of the target are shown in Table 1. The number of particles was decreased to a background level (five particles) or less at the time of 1.4 kWh sputtering, however, the burn-in time was long compared to that in Example 1.

### Comparative Example 3

Target materials having the same composition as that in Example 1 were produced into a target by performing machining after cutting with a lathe by surface grinding and then polishing finishing. The finishing quantity was 25 μm (surface grinding)+1 μm (polishing). The results of XRD measurement was that the integral width of the peak at 50°, the highest of single peaks, was 0.8, which exceeded the range of the present invention.

As a result of sputtering the target, the number of particles was decreased to a background level (five particles) or less at the time of 1.3 kWh sputtering, however, the burn-in time was long compared to that in Example 1.

### Example 2

A Co powder having an average grain size of 3 μm, a Cr powder having an average grain size of 5 μm, a Pt powder having an average grain size of 1 μm, a TiO₂ powder having an average grain size of 1 μm, and a Co coarse powder having a diameter in a range of 50 to 300 μm were prepared as raw material powders. The Co powder, the Cr powder, the Pt powder, the TiO₂ powder, and the Co coarse powder, were weighed to obtain a target composition 54Co-20Cr-15Pt-5TiO₂-6CoO (mol %). Then, a target material was produced as in Example 1.

The target was produced by performing machining after cutting with a lathe by surface grinding of 50 μm. The finishing quantity was 50 μm. In order to estimate the residual strain remaining on the target surface, XRD was measured. The integral width of the peak at 50°, the highest of single peaks, was 0.7.

As a result of sputtering the target, the number of particles was decreased to a background level (five particles) or less at the time of 0.8 kWh sputtering, which was a satisfactory result. The results are also shown in Table 1.

### Comparative Example 4

Target materials having the same composition as that in Example 2 were produced into a target by performing machining after cutting with a lathe by surface grinding of 25 μm. The results of XRD measurement was that the integral width of the peak at 50°, the highest of single peaks, was 1.1, which exceeded the range of the present invention.

As a result of sputtering the target, the number of particles was decreased to a background level (five particles) or less at the time of 2.3 kWh sputtering, however, the burn-in time was long compared to that in Example 2. The results are also shown in Table 1.

### Example 3

A Co powder having an average grain size of 3 μm, a Cr powder having an average grain size of 5 μm, a Pt powder having an average grain size of 1 μm, a TiO₂ powder having an average grain size of 1 μm, a SiO₂ powder having an average grain size of 1 μm, a Cr₂O₃ powder having an average grain size of 1 μm, and a Co coarse powder having a diameter in a range of 50 to 300 μm were prepared as raw material powders. The Co powder, the Cr powder, the Pt powder, the TiO₂ powder, the SiO₂ powder, the Cr₂O₃ powder, and the Co coarse powder, were weighed to obtain a target composition 61Co-15Cr-15Pt-3TiO₂-3SiO₂-3Cr₂O₃ (mol %). Then, a target material was produced as in Example 1.

A target was produced by performing machining after cutting with a lathe by surface grinding and then polishing finishing. The finishing quantity was 25 μm (surface grinding)+1 μm (polishing). In order to estimate the residual strain remaining on the target surface, XRD was measured. The integral width of the peak at 50°, the highest of single peaks, was 0.7.

As a result of sputtering the target, the number of particles was decreased to a background level (five particles) or less at the time of 0.9 kWh sputtering, which was a satisfactory result. The results are also shown in Table 1.

### Comparative Example 5

Target materials having the same composition as that in Example 3 were produced into a target by performing machining after cutting with a lathe by surface grinding only. The results of XRD measurement was that the integral width of the peak at 50°, the highest of single peaks, was 1.3, which exceeded the range of the present invention.

As a result of sputtering the target, the number of particles was decreased to a background level (five particles) or less at the time of 2.8 kWh sputtering, however, the burn-in time was long compared to that in Example 3. The results are also shown in Table 1.

### Example 4

A Co powder having an average grain size of 3 μm, a Cr powder having an average grain size of 5 μm, a TiO₂ powder having an average grain size of 1 μm, and a Co coarse powder having a diameter in a range of 50 to 300 μm were prepared as raw material powders. The Co powder, the Cr powder, the TiO₂ powder, and the Co coarse powder, were weighed to obtain a target composition 60Co-30Cr-10TiO₂ (mol %). Then, a target material was produced as in Example 1.

A target was produced by performing machining after cutting with a lathe by polishing finishing. The finishing quantity was 1 μm. In order to estimate the residual strain remaining on the target surface, XRD was measured. The integral width of the peak at 50°, the highest of single peaks, was 0.6, which satisfied the condition of the present invention.

As a result of sputtering the target, the number of particles was decreased to a background level (five particles) or less at the time of 0.7 kWh sputtering, which was a satisfactory result. The results are also shown in Table 1.

### Comparative Example 6

Target materials having the same composition as that in Example 3 were produced into a target by performing machining after cutting with a lathe by surface grinding. The finishing quantity was 25 μm. The results of XRD measurement was that the integral width of the peak at 50°, the highest of single peaks, was 1.2, which exceeded the range of the present invention.

As a result of sputtering the target, the number of particles was decreased to a background level (five particles) or less at the time of 1.3 kWh sputtering, however, the burn-in time was long compared to that in Example 4. The results are also shown in Table 1.

Although the examples described above do not show a metal matrix phase containing at least one element selected from B, Ti, V, Mn, Zr, Nb, Ru, Mo, Ta, and W in an amount of 0.5 to 10 mol %, these elements are those for improving the characteristics of magnetic materials but do not significantly change the integral width of the main peak in XRD measurement. It has been confirmed that results similar to those in examples were obtained also in the cases of the metal matrix phases containing these elements.

It has been also confirmed that the addition of at least one oxide selected from SiO₂, TiO₂, Ti₂O₃, Cr₂O₃, Ta₂O₅, Ti₅O₉, B₂O₃, CoO, and Co₃O₄ or the addition of an oxide other than those described in the examples provides similar results to those in the examples.

The present invention provides a non-magnetic material grain-dispersed sputtering target performing stable electric discharge during sputtering by inhibiting the generation of initial particles during sputtering and considerably shortening the burn-in time. Consequently, the target lifetime is elongated to allow production of a magnetic material thin film at a low cost. Furthermore, the quality of the film formed by sputtering can be significantly improved. The sputtering target is useful as a ferromagnetic sputtering target for forming a magnetic material thin film for a magnetic recording medium, in particular, a film for a hard disk drive recording layer.

1. A sputtering target comprising a metal matrix phase containing Co and an oxide phase of dispersed oxide grains in an amount of 6 to 25 mol %, wherein the integral width of the highest peak among single peaks of XRD is 0.7 or less.

2. The sputtering target according to claim 1, wherein the metal matrix phase is composed of 5 mol % or more and 40 mol % or less of Cr and the remainder being Co and inevitable impurities.

3. The sputtering target according to claim 1, wherein the metal matrix phase is composed of 5 mol % or more and 40 mol % or less of Cr, 5 mol % or more and 30 mol % or less of Pt, and the remainder being Co and inevitable impurities.

4. The sputtering target according to claim 3, wherein the oxide phase is composed of at least one oxide selected from SiO₂, TiO₂, Ti₂O₃, Cr₂O₃, Ta₂O₅, Ti₅O₉, B₂O₃, CoO, and Co₃O₄; and the amount of the oxide phase is 5 to 25 mol %.

5. The sputtering target according to claim 4, wherein the metal matrix phase contains at least one element selected from B, Ti, V, Mn, Zr, Nb, Ru, Mo, Ta, and W in an amount of 0.5 to 10 mol %.

6. The sputtering target according to claim 2, wherein the oxide phase is composed of at least one oxide selected from SiO₂, TiO₂, Ti₂O₃, Cr₂O₃, Ta₂O₅, Ti₅O₉, B₂O₃, CoO, and Co₃O₄; and the amount of the oxide phase is 5 to 25 mol %.

7. The sputtering target according to claim 6, wherein the metal matrix phase contains at least one element selected from B, Ti, V, Mn, Zr, Nb, Ru, Mo, Ta, and W in an amount of 0.5 to 10 mol %.

8. The sputtering target according to claim 1, wherein the oxide phase is composed of at least one oxide selected from SiO₂, TiO₂, Ti₂O₃, Cr₂O₃, Ta₂O₅, Ti₅O₉, B₂O₃, CoO, and Co₃O₄; and the amount of the oxide phase is 5 to 25 mol %.

9. The sputtering target according to claim 1, wherein the metal matrix phase contains at least one element selected from B, Ti, V, Mn, Zr, Nb, Ru, Mo, Ta, and W in an amount of 0.5 to 10 mol %.
